(19) United States
(12) Patent Application Publication
(10) Pub. No.: US 2024/0196599 A1
(43) Pub. Date: Jun. 13, 2024

(54) SEMICONDUCTOR DEVICE

(71) Applicant: SAMSUNG ELECTRONICS CO., LTD., Suwon-si (KR)

(72) Inventors: Jaekang KOH, Suwon-si (KR); Byeongguk KO, Suwon-si (KR); Chanyoung KIM, Suwon-si (KR); Sangkoo NAM, Suwon-si (KR); Yongsoon CHOI, Suwon-si (KR)

(21) Appl. No.: 18/512,135

(22) Filed: Nov. 17, 2023

(30) Foreign Application Priority Data
Dec. 8, 2022 (KR) 10-2022-0170205

(51) Int. Cl. H10B 12/00

(52) U.S. Cl. CPC H10B 12/482; H10B 12/315

(57) ABSTRACT

A semiconductor device includes: an active pattern disposed on a substrate; a gate structure disposed on the active pattern; a bit line structure disposed on the active pattern, and including a first conductive pattern, a second conductive pattern and an insulation structure stacked on each other, a lower spacer structure disposed on a sidewall of the bit line structure; an upper spacer structure disposed on the lower spacer structure, wherein the upper spacer structure is disposed on an upper portion of the sidewall of the bit line structure; a contact plug structure disposed on the active pattern, wherein the contact plug structure is spaced apart from the bit line structure; and a capacitor disposed on the contact plug structure, wherein the lower spacer structure includes: a first spacer partially covering a sidewall of the first conductive pattern, and including air; and a second spacer disposed on the first spacer.

### CROSS-REFERENCE TO RELATED APPLICATION

This application claims priority under 35 U.S.C. § 119 to Korean Patent Application No. 10-2022-0170205 filed on Dec. 8, 2022 in the Korean Intellectual Property Office, the disclosure of which is incorporated by reference herein in its entirety.

### TECHNICAL FIELD

Example embodiments of the present inventive concept relate to a semiconductor device. More particularly, example embodiments of the present inventive concept relate to a DRAM device.

### DISCUSSION OF RELATED ART

Generally, in a DRAM device, a bit line structure may include a first conductive pattern, a barrier pattern, a second conductive pattern, a mask, an etch stop pattern and a capping pattern, which are sequentially stacked on each other, and a spacer structure may be formed on a sidewall of the bit line structure to prevent electrical short between the bit line structure and an adjacent contact plug.

However, as a width of the bit line structure becomes smaller to increase an integration degree of the DRAM device, the bit line structure may be tilted or broken. Additionally, an electrical short between the bit line structure and the contact plug may occur because a distance between the bit line structure and the contact plug might not be sufficiently large.

### SUMMARY

According to example embodiments of the present inventive concept, a semiconductor device includes: an active pattern disposed on a substrate; a gate structure disposed on an upper portion of the active pattern; a bit line structure disposed on the active pattern, wherein the bit line structure includes a first conductive pattern, a second conductive pattern and an insulation structure stacked on each other in a vertical direction substantially perpendicular to an upper surface of the substrate; a lower spacer structure disposed on a lower portion of a sidewall of the bit line structure; an upper spacer structure disposed on the lower spacer structure, wherein the upper spacer structure is disposed on an upper portion of the sidewall of the bit line structure; a contact plug structure disposed on the active pattern, wherein the contact plug structure is spaced apart from the bit line structure, and a capacitor disposed on the contact plug structure, wherein the lower spacer structure includes: a first spacer partially covering a sidewall of the first conductive pattern, and including air; and a second spacer disposed on the first spacer.

According to example embodiments of the present inventive concept, a semiconductor device includes: an active pattern disposed on a substrate; an isolation pattern disposed on the substrate, wherein the isolation pattern covers a sidewall of the active pattern; a gate structure disposed on an upper portion of the active pattern and an upper portion of the isolation pattern, wherein the gate structure extends in a first direction substantially parallel to an upper surface of the substrate; an insulation pattern structure disposed on the active pattern, the isolation pattern and the gate structure; a bit line structure extending on the active pattern and the insulation pattern structure in a second direction, wherein the second direction is substantially parallel to the upper surface of the substrate and crosses the first direction, and wherein the bit line structure includes a first conductive pattern structure, a second conductive pattern and an insulation structure sequentially stacked in a vertical direction substantially perpendicular to the upper surface of the substrate; a lower spacer structure disposed on a lower portion of a sidewall of the bit line structure, and including a first spacer, a second spacer and a third spacer; an upper spacer structure disposed on the lower spacer structure and on an upper portion of the sidewall of the bit line structure; a contact plug structure disposed on the active pattern, and spaced apart from the bit line structure; and a capacitor disposed on the contact plug structure, wherein the first conductive pattern structure includes a lower portion, a middle portion and an upper portion sequentially stacked on each other in the vertical direction, and wherein a first width, in the first direction, of the lower portion of the first conductive pattern structure is greater than a second width, in the first direction, of the middle portion of the first conductive pattern structure.

According to example embodiments of the present inventive concept, a semiconductor device includes: an active pattern disposed on a substrate; a gate structure disposed on an upper portion of the active pattern, a bit line structure disposed on the active pattern, wherein the bit line structure includes a first conductive pattern, a second conductive pattern and an insulation structure stacked on each other in a vertical direction substantially perpendicular to an upper surface of the substrate; a lower spacer structure disposed on a lower portion of a sidewall of the bit line structure; an upper spacer structure disposed on the lower spacer structure, and disposed on an upper portion of the sidewall of the bit line structure; a contact plug structure disposed on the active pattern, wherein the contact plug structure is spaced apart from the bit line structure; and a capacitor disposed on the contact plug structure, wherein the first conductive pattern includes: a lower portion contacting an upper surface of the active pattern; a middle portion disposed on the lower portion; and an upper portion disposed on the middle portion, wherein the upper portion of the first conductive pattern has a shape of a rectangular pillar or a rectangular pillar with rounded vertices, and wherein the lower spacer structure covers sidewalls of the lower portion and the middle portion of the first conductive pattern, and the upper spacer structure covers a sidewall of the upper portion of the first conductive pattern.

### BRIEF DESCRIPTION OF THE DRAWINGS

FIGS. 1 and 2 are a plan view and a cross-sectional view illustrating a semiconductor device in accordance with example embodiments of the present inventive concept.

FIGS. 3, 4, 5, 6, 7, 8, 9, 10, 11, 12, 13, 14, 15, 16, 17, 18, 19, 20, 21, 22, 23, 24, 25, 26, 27, and 28 are plan views and cross-sectional views illustrating a method of manufacturing a semiconductor device according to example embodiments of the present inventive concept.

FIG. 29 is a cross-sectional view illustrating a semiconductor device according to example embodiments of the present inventive concept.

FIG. 30 is a cross-sectional view illustrating a semiconductor device according to example embodiments of the present inventive concept.

FIG. 31 is a cross-sectional view illustrating a method of manufacturing a semiconductor device according to example embodiments of the present inventive concept.

### DETAILED DESCRIPTION OF THE EMBODIMENTS

The above and other aspects and features of the semiconductor devices and the methods of manufacturing the same in accordance with example embodiments of the present inventive concept will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate 100, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 100 may be referred to as a vertical direction.

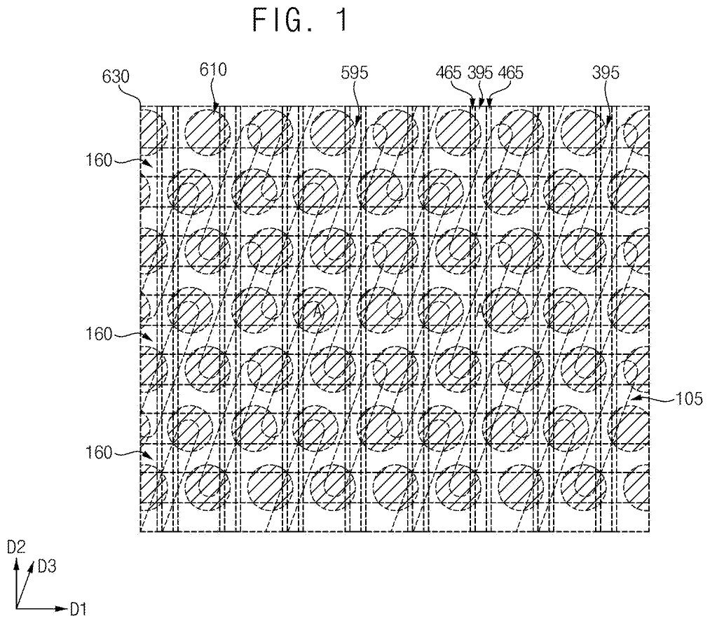

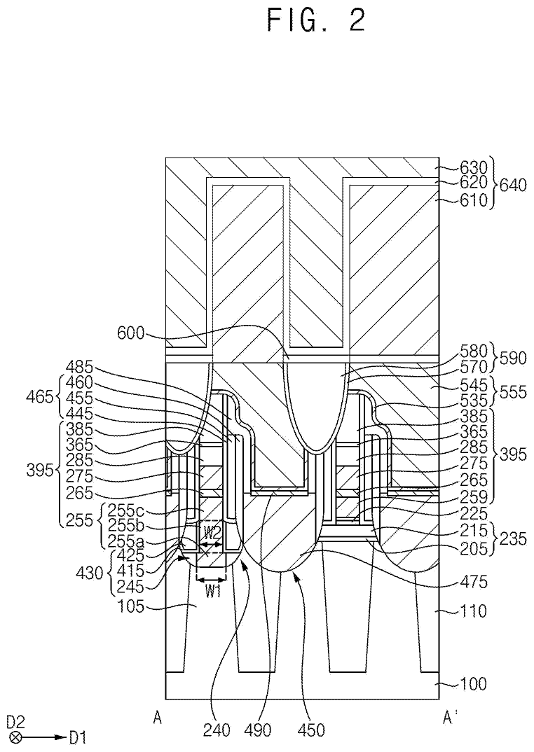

FIG. 1 is a plan view illustrating a semiconductor device in accordance with example embodiments of the present inventive concept, and FIG. 2 is a cross-sectional view taken along line A-A′ of FIG. 1.

Referring to FIGS. 1 and 2, the semiconductor device may include an active pattern 105, an isolation pattern 110, a gate structure 160, a bit line structure 395, a first lower spacer structure 430, an upper spacer structure 465, a seventh spacer 485, a contact plug structure and a capacitor 640 on a substrate 100.

The semiconductor device may further include first and second insulation pattern structures 235 and 590, a second etch stop pattern 600 and a second capping pattern 480.

The substrate 100 may include a semiconductor material, e.g., silicon, germanium, silicon-germanium, etc., or III-V semiconductor compounds, e.g., GaP, GaAs, GaSb, etc. In some example embodiments of the present inventive concept, the substrate 100 may include a silicon-on-insulator (SOI) substrate or a germanium-on-insulator (GOI) substrate.

The active pattern 105 may extend in the third direction D3, and a plurality of active patterns 105 may be spaced apart from each other in the first and second directions D1 and D2. A sidewall of the active pattern 105 may be covered by the isolation pattern 110. The active pattern 105 may include substantially the same material as that of the substrate 100, and the isolation pattern 110 may include an oxide, e.g., silicon oxide.

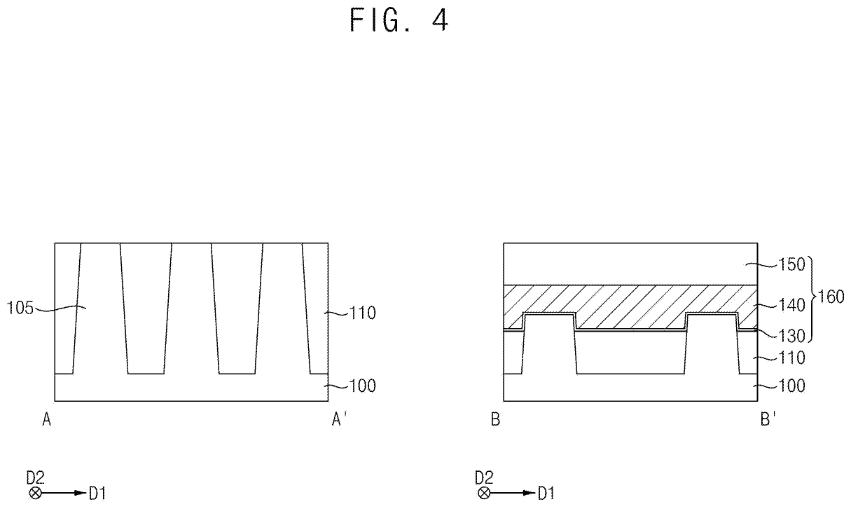

Referring to FIGS. 1 and 2 together with FIG. 4, the gate structure 160 may be formed in a second recess extending in the first direction D1 through upper portions of the active pattern 105 and the isolation pattern 110. The gate structure 160 may include a gate insulation pattern 130, a gate electrode 140, and a gate mask 150. The gate insulation pattern 130 may be disposed on a bottom and a sidewall of the second recess, and the gate electrode 140 may be disposed on a portion of the gate insulation pattern 130 that is disposed on the bottom and a lower sidewall of the second recess. The gate mask 150 may be disposed on the gate electrode 140 and may fill an upper portion of the second recess.

The gate insulation pattern 130 may include an oxide, e.g., silicon oxide. The gate electrode 140 may include, e.g., a metal, a metal nitride, a metal silicide, etc., and the gate mask 150 may include an insulating nitride, e.g., silicon nitride.

In example embodiments of the present inventive concept, the gate structure 160 may extend in the first direction D1, and a plurality of gate structures 160 may be spaced apart from each other in the second direction D2.

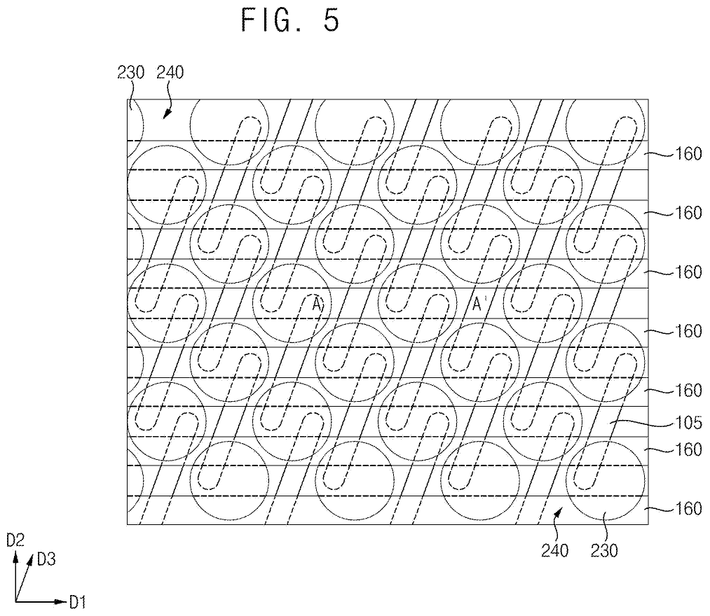

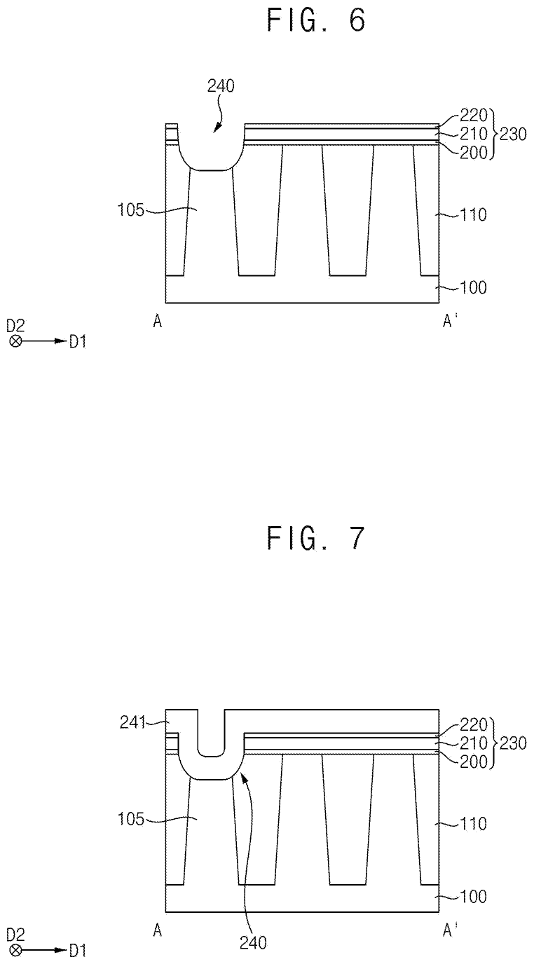

Referring to FIGS. 1 and 2 together with FIGS. 5 and 6, a first opening 240 extending through an insulating layer structure 230 and exposing upper surfaces of the active pattern 105 may be formed. In addition, the isolation pattern 110 and the gate mask 150 of the gate structure 160 may be formed, and an upper surface of a central portion in the third direction D3 of the active pattern 105 may be exposed by the first opening 240.

In example embodiments of the present inventive concept, an area of a bottom of the first opening 240 may be greater than an area of the upper surface of the active pattern 105. Thus, the first opening 240 may also expose an upper surface of a portion of the isolation pattern 110 that is adjacent to the active pattern 105. Additionally, the first opening 240 may extend through an upper portion of the active pattern 105 and the portion of the isolation pattern 110 adjacent thereto, and thus, the bottom of the first opening 240 may be lower than an upper surface of each of opposite edge portions in the third direction D3 of the active pattern 105.

In example embodiments of the present inventive concept, the first opening 240 may be spaced apart from each other in the first and second directions D1 and D2.

In example embodiments of the present inventive concept, the bit line structure 395 may extend in the second direction D2 on the substrate 100, and a plurality of bit line structures 395 may be spaced apart from each other in the first direction D1. The bit line structure 395 may include a first conductive pattern 255, a first barrier pattern 265, a third conductive pattern 275, a second mask 285, a first etch stop pattern 365 and a first capping pattern 385 sequentially stacked in the vertical direction on the first opening 240, and the bit line structure 395 may include a second conductive pattern 259, the first barrier pattern 265, the third conductive pattern 275, the second mask 285, the first etch stop pattern 365 and the first capping pattern 385 sequentially stacked in the vertical direction on the first insulation pattern structure 235 at an outside the first opening 240.

The first conductive pattern 255 may have a lower portion 255a, a middle portion 255b, and an upper portion 255c. The lower portion 255a may be disposed at a lower portion of the first opening 240 and contacting an upper surface of a central portion of the active pattern 105. The middle portion 255b may be disposed on the lower portion 255a, and an upper portion 255c may be disposed on the middle portion 255b. The lower portion 255a and the middle portion 255b of the first conductive pattern 255 may be disposed within the first opening 240. The upper portion 255c of the first conductive pattern 255 may protrude upwardly from the first opening 240, and an upper surface of the middle portion 255b of the first conductive pattern 255 may be substantially coplanar with an upper surface of the third insulating pattern 225.

In example embodiments of the present inventive concept, each of the lower portion 255a and the middle portion 255b of the first conductive pattern 255 may have a shape of, for example, a circle, a square, or a square with rounded vertices in a plan view. Accordingly, each of the lower portion 255a and the middle portion 255b of the first conductive pattern 255 may have the shape of, for example, a cylinder, a square pillar, or a square pillar with rounded vertices.

In an example embodiment of the present inventive concept, as the lower portion 255a and the middle portion 255b of the first conductive pattern 255, the upper portion 255c of the first conductive pattern 255 may have a shape of, for example, a circle, a square or a square with rounded vertices in a plan view. Accordingly, the upper portion 255c of the first conductive pattern 255 may have, for example, a shape of a cylinder, a square pillar, or a square pillar with rounded vertices.

In an example embodiment of the present inventive concept, the upper portion 255c of the first conductive pattern 255 may have a shape of a rectangle of which a width in the second direction D2 is larger than a width in the first direction D1, or a shape of a rectangle with rounded vertices. Accordingly, the upper portion 255c of the first conductive pattern 255 may have a shape of, for example, a rectangular pillar or a rectangular pillar with rounded vertices.

The lower portion 255a of the first conductive pattern 255 may have a first width W1 in the first direction D1, and each of the middle portion 255b and the upper portion 255c of the first conductive pattern 255 may have a second width W2 in the first direction D1. In an example embodiment of the present inventive concept, the second width W2 may be smaller than the first width W1. In an example embodiment of the present inventive concept, the second width W2 may be substantially the same as the first width W1.

In example embodiments of the present inventive concept, a plurality of first conductive patterns 255 may be spaced apart from each other in the second direction D2, and the second conductive pattern 259 may be formed between and contact ones of the first conductive patterns 255 adjacent to each other in the second direction D2. In example embodiments of the present inventive concept, an upper surface of the second conductive pattern 259 and an upper surface of the first conductive pattern 255 may be substantially coplanar to each other.

In example embodiments of the present inventive concept, each of the first and second conductive patterns 255 and 259 may include polysilicon doped with n-type impurities, for example, phosphorus(P), arsenic(As), etc. In an example embodiment of the present inventive concept, the first and second conductive patterns 255 and 259 may include the same material as each other, that is, polysilicon doped with the same impurities, and accordingly, the first and second conductive patterns 255 and 259 may be merged with each other and not distinguished from each other. In an example embodiment of the present inventive concept, the first and second conductive patterns 255 and 259 may include different materials from each other, that is, polysilicon doped with different impurities, and thus, the first and second conductive patterns 255 and 259 may be distinguished from each other.

The first and second conductive patterns 255 and 259 may collectively form a conductive pattern structure, and the conductive pattern structure, the first barrier pattern 265 and the third conductive pattern 275 may collectively form a conductive structure. The second mask 285, the first etch stop pattern 365 and the first capping pattern 385 may collectively form an insulation structure.

For example, the first barrier pattern 265 may include a metal nitride, e.g., titanium nitride, or a metal silicon nitride, e.g., titanium silicon nitride. For example, the third conductive pattern 275 may include a metal, e.g., tungsten, and each of the second mask 285, the first etch stop pattern 365 and the first capping pattern 385 may include an insulating nitride, e.g., silicon nitride.

The first lower spacer structure 430 may be disposed in the first opening 240, and may contact a sidewall of the first opening 240 and sidewalls of the lower portion 255a and the middle portion 255b of the first conductive pattern 255. The first lower spacer structure 430 may include first to third spacers 245, 415 and 425.

The first spacer 245 may cover a lower sidewall of the first opening 240 and the sidewall of the lower portion 255a of the first conductive pattern 255. In example embodiments of the present inventive concept, the first spacer 245 may include air.

The second spacer 415 may cover the sidewall of the middle portion 255b of the first conductive pattern 255 and an upper surface of the first spacer 245, and the third spacer 425 may be disposed on the second spacer 415, so that an inner sidewall and a bottom of the third spacer 245 may be covered by the second spacer 415. The second spacer 415 may include, for example, silicon oxide, silicon carbonitride, or metal oxide, and the third spacer 425 may include, for example, an insulating nitride such as silicon nitride.

The first insulation pattern structure 235 may be formed on the active pattern 105 and the isolation pattern 110 under the bit line structure 395, and may include first, second and third insulation patterns 205, 215 and 225 sequentially stacked on each other in the vertical direction. The first and third insulation patterns 205 and 225 may include an oxide, e.g., silicon oxide, and the second insulation pattern 215 may include an insulating nitride, e.g., silicon nitride.

The contact plug structure may include a lower contact plug 475, a metal silicide pattern 490 and an upper contact plug 555 sequentially stacked on each other in the vertical direction on the active pattern 105 and the isolation pattern 110.

The lower contact plug 475 may contact the upper surface of each of opposite edge portions in the third direction D3 of the active pattern 105. In example embodiments of the present inventive concept, a plurality of lower contact plugs 475 may be spaced apart from each other in the second direction D2, and a second capping pattern 480 may be formed between neighboring ones of the lower contact plugs 475 in the second direction D2. For example, the second capping pattern 480 may include an insulating nitride, e.g., silicon nitride.

For example, the lower contact plug 475 may include, e.g., doped polysilicon, and the metal silicide pattern 490 may include, e.g., titanium silicide, cobalt silicide, nickel silicide, etc.

The upper contact plug 555 may include a second metal pattern 545 and a second barrier pattern 535 that covers a lower surface of the second metal pattern 545. For example, the second metal pattern 545 may include a metal, e.g., tungsten, and the second barrier pattern 535 may include a metal nitride, e.g., titanium nitride.

In example embodiments of the present inventive concept, a plurality of upper contact plugs 555 may be spaced apart from each other in the first and second directions D1 and D2, and may be arranged in a honeycomb pattern or a lattice pattern in a plan view. Each of the upper contact plugs 555 may have a shape of, e.g., a circle, an ellipse, or a polygon in a plan view.

The upper spacer structure 465 may include a fourth spacer 445 covering an upper sidewall of the bit line structure 395, that is, a sidewall of the upper portion 255c of the first conductive pattern 255, an upper sidewall of the middle portion 255b of the first conductive pattern 255, sidewalls of the first barrier pattern 265, the third conductive pattern 275, the second mask 285, the first etch stop pattern 365 and the first capping pattern 385, a sidewall of the third insulation pattern 225 and an upper surface of the first lower spacer structure 430. The upper spacer structure 465 may further include a fifth spacer 455 that may be disposed on a lower portion of an outer sidewall of the fourth spacer 445. The upper spacer structure 465 may additionally include a sixth spacer 460 that may be disposed on an outer sidewall of the fifth spacer 455, a sidewall of the first insulation structure 235 and a portion of an upper sidewall of the first lower spacer structure 430.

In example embodiments of the present inventive concept, a cross-section in the first direction D1 of the fourth spacer 445 may have an “L” shape.

For example, each of the fourth and sixth spacers 445 and 460 may include an insulating nitride, e.g., silicon nitride, and the fifth spacer 455 may include an oxide or air.

The seventh spacer 485 may cover an outer sidewall of a portion of the fourth spacer 445, which is on the upper sidewall of the bit line structure 395, an upper surface of the fifth spacer 455 and an upper surface and an upper portion of an outer sidewall of the sixth spacer 465. For example, the seventh spacer 485 may include an insulating nitride, e.g., silicon nitride.

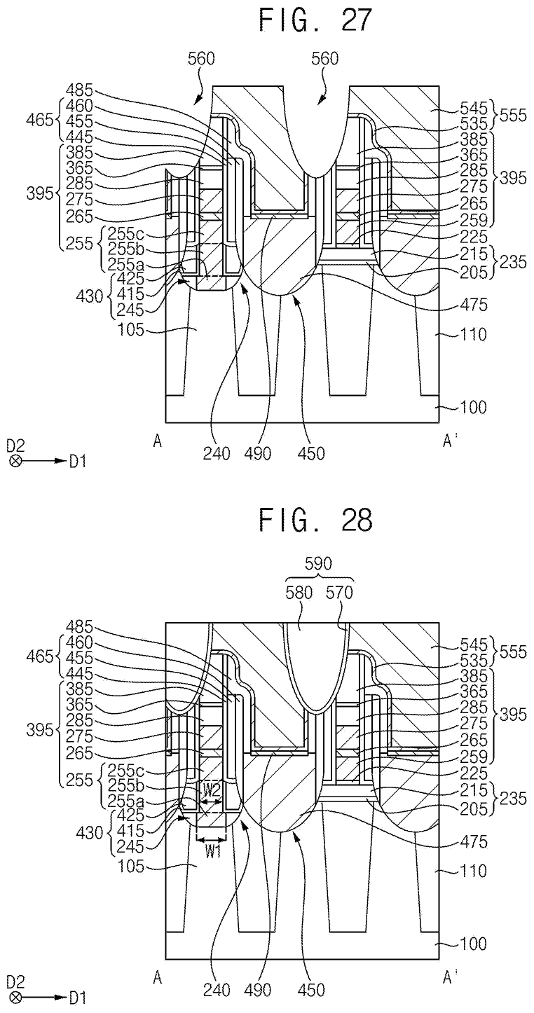

Referring to FIGS. 1 and 2 together with FIGS. 27 and 28, the second insulation pattern structure 590 may include a fourth insulation pattern 570 and a fifth insulation pattern 580. The fourth insulation pattern 570 may be disposed on an inner wall of a sixth opening 560, which may extend through the upper contact plug 555, a portion of the insulation structure of the bit line structure 395 and a portion of upper spacer structure 465 and may at least partially surround the upper contact plug 555 in a plan view. The fifth insulation pattern 580 may be disposed on the fourth insulation pattern 570 and may fill a remaining portion of the sixth opening 560.

If the fifth spacer 455 includes air, a top end of the air spacer 435 may be closed by the fourth insulation pattern 570.

For example, the fourth and fifth insulation patterns 570 and 580 may include an insulating nitride, e.g., silicon nitride.

The second etch stop pattern 600 may be disposed on the second insulation pattern structure 590. For example, the second etch stop pattern 600 may include, an insulating nitride, e.g., silicon boronitride, silicon nitride, etc.

The capacitor 640 may be disposed on the upper contact plug 555. The capacitor 640 may include a lower electrode 610 having a shape of a pillar or a cylinder, a dielectric layer 620 on a surface of the lower electrode 610, and an upper electrode 630 on the dielectric layer 620.

For example, the lower electrode 610 may include, e.g., a metal, a metal nitride, a metal silicide, polysilicon doped with impurities, etc. For example, the dielectric layer 620 may include, e.g., a metal oxide, and the upper electrode 630 may include, e.g., a metal, a metal nitride, a metal silicide, silicon-germanium (SiGe) doped with impurities, etc.

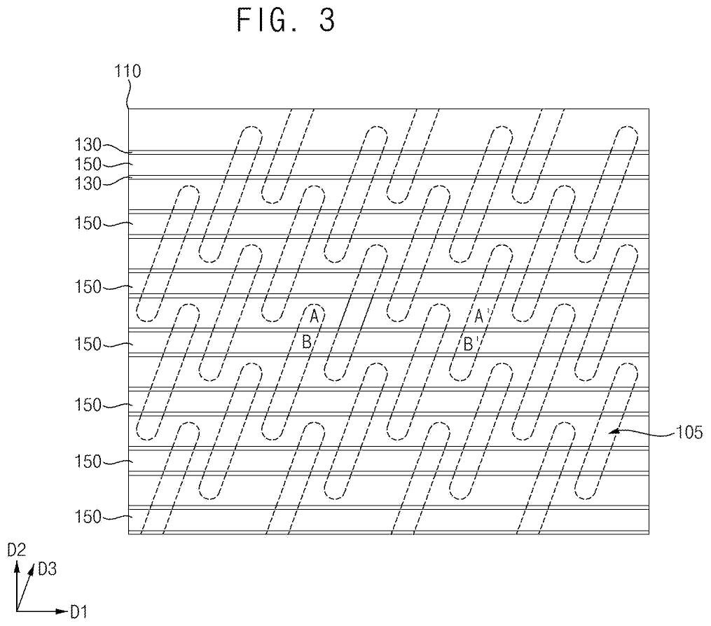

In the semiconductor device, the first spacer 245 and the first lower spacer structure may be disposed between the first conductive pattern 255 of the bit line structure 395 in the first opening 240 and the lower contact plug 475, and accordingly, the first conductive pattern 255 and the lower contact plug 475 may be electrically insulated from each other. For example, as illustrated with reference to FIGS. 3 to 28, the first conductive pattern 255 might not contact a sidewall of the first opening 240 due to the first spacer 245, and thus an electrical short between the bit line structure 395 and the lower contact plug 475 may be prevented.

Additionally, the first spacer 245 may include air that has a low dielectric constant, so that parasitic capacitance between the bit line structure 395 and the lower contact plug 475 may be reduced.

FIGS. 3 to 28 are plan views and cross-sectional views illustrating a method of manufacturing a semiconductor device according to example embodiments of the present inventive concept.

For example, FIGS. 3, 5, 13, 22 and 26 are the plan views, FIG. 4 includes cross-sectional views taken along lines A-A′ and B-B′ of FIG. 3, and FIGS. 6-12, 14-21, 23-25 and 27-28 are cross-sectional views taken along lines A-A′, respectively, of corresponding plan views.

Referring to FIGS. 3 and 4, an upper portion of a substrate 100 may be removed to form a first recess, and an isolation pattern 110 may be formed in the first recess.

As the isolation pattern 110 is formed on the substrate 100, an active pattern 105 of which a sidewall is covered by the isolation pattern 110 may be defined.

The active pattern 105 and the isolation pattern 110 on the substrate 100 may be partially etched to form a second recess extending in the first direction D1, and a gate structure 160 may be formed in the second recess. In example embodiments of the present inventive concept, the gate structure 160 may extend in the first direction D1, and a plurality of gate structures 160 may be spaced apart from each other in the second direction D2.

Referring to FIGS. 5 and 6, an insulating layer structure 230 may be formed on the active pattern 105, the isolation pattern 110, and the gate structure 160. The insulating layer structure 230 may include first to third insulating layers 200, 210, and 220 sequentially stacked on each other.

The insulating layer structure 230 may be patterned, and the active pattern 105, the isolation pattern 110, and the gate mask 150 included in the gate structure 160 may be partially etched by using the patterned insulating layer structure 230 as an etching mask to form a first opening 240. In example embodiments of the present inventive concept, the insulating layer structure 230 may have a circular shape or an elliptical shape in a plain view, and a plurality of insulating layer structures 230 may be spaced apart from each other in the first and second directions D1 and D2. Each of the insulating layer structures 230 may overlap end portions of ones of the active patterns 105 neighboring in the third direction D3, which may face each other, in a vertical direction substantially orthogonal to the upper surface of the substrate 100.

Referring to FIG. 7, a sacrificial spacer layer 241 may be formed on the first insulating layer structure 230, the active pattern 105, the isolation pattern 110 and the gate structure 160 that are exposed by the first opening 240.

The sacrificial spacer layer 241 may include a polymer that decomposes at a low temperature, for example, below about 300° C., and the sacrificial spacer layer 241 may include carbon(C).

In example embodiments of the present inventive concept, the polymer may be derived from monomers such as 1,4-bis (hydroxymethyl)cyclohexane, phenylvinylketone, cyclohexane-1,2-diyl dimethane diyl dimethanesulfonate, 1,3-bis (4-methoxyphenyl)cyclohexane, 1,4-cyclohexane dimethanol, dimethyl cyclohexane-1,4-dicarboxylate, etc.

Referring to FIG. 8, an anisotropic etching process may be performed on the sacrificial spacer layer 241, and a portion of the sacrificial spacer layer 241, which is on an upper surface of the first insulating layer structure 230 and an upper surface of the active pattern 105 that is exposed by the first opening 240, may be removed to form a sacrificial spacer 243.

The sacrificial spacer 243 may be formed to cover a sidewall of the first opening 240, and the upper surface of the active pattern 105 may be partially exposed again without being covered by the sacrificial spacer 243.

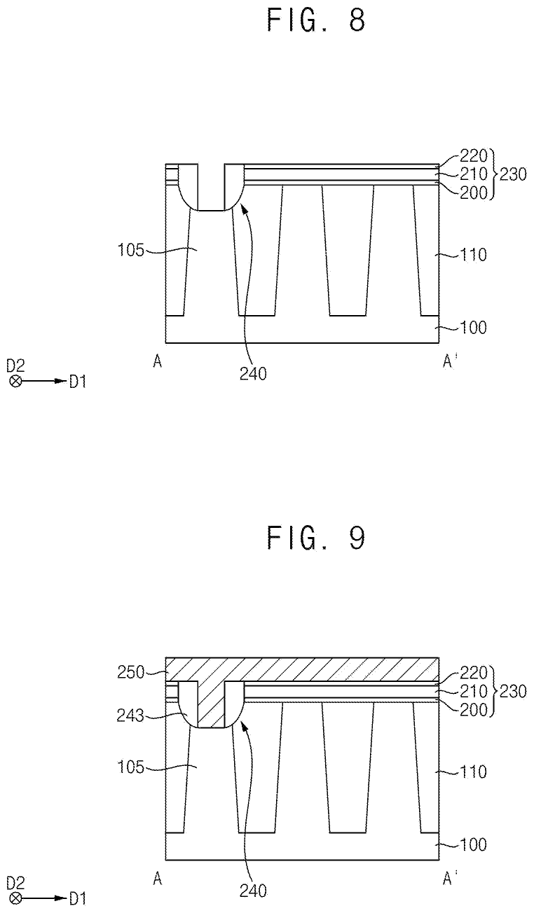

Referring to FIG. 9, a first conductive layer 250 may be formed on the first insulating layer structure 230, the sacrificial spacer 243 and the partially exposed upper surface of the active pattern 105 to fill a remaining portion of the first opening 240.

In example embodiments of the present inventive concept, a portion of the first conductive layer 250 in the first opening 240, that is, a lower portion of the first conductive layer 250 may have a shape of, for example, a circle, a square or a square with rounded vertices in a plan view, and may have a first width W1 in the first direction D1.

In example embodiments of the present inventive concept, the first conductive layer 250 may include polysilicon doped with n-type impurities, for example, phosphorus (P) or arsenic (As).

Referring to FIG. 10, a first mask layer and a photoresist layer may be sequentially formed on the first conductive layer 250. The photoresist layer may be patterned to form a photoresist pattern 253, and the first mask layer may be etched by using the photoresist pattern 253 as an etching mask to form the first mask 251.

In example embodiments of the present inventive concept, the first mask 251 may have the first width W1 in the first direction D1, and may overlap, in the vertical direction, the first conductive layer 250. In an example embodiment of the present inventive concept, the first mask 251 may have a shape of a circle, a square, or a square with rounded vertices in a plan view. In an example embodiment of the present inventive concept, the first mask 251 may have a shape of rectangle or a rectangle with rounded vertices having a length in the second direction D2 greater than a length in the first direction D1 in a plan view.

In example embodiments of the present inventive concept, the first mask 251 may have a multi-layer structure including a plurality of layers stacked in the vertical direction.

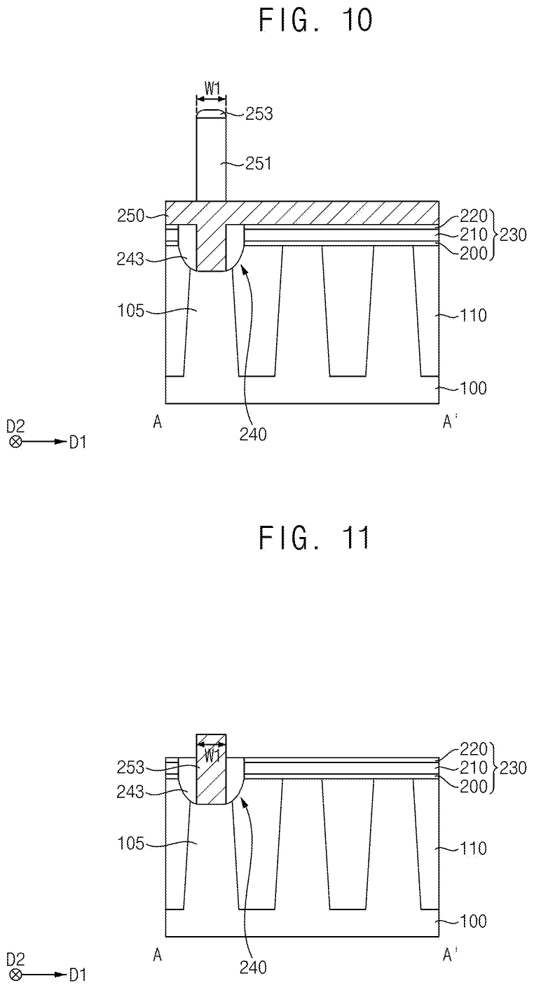

Referring to FIG. 11, after removing the photoresist pattern 253, the first conductive layer 250 may be patterned by performing a first etching process using the first mask 251 as an etching mask. Accordingly, the first conductive layer 250 may be transformed into a first preliminary conductive pattern 253.

The first etching process may be performed by, for example, a dry etching process.

In example embodiments of the present inventive concept, the first preliminary conductive pattern 253 may include a lower portion, which is disposed in the first opening 240, and an upper portion that is disposed on the lower portion and positioned higher than an upper surface of the sacrificial spacer 243 and the upper surface of the first insulating layer structure 230. The first preliminary conductive pattern 253 may have the first width W1 in the first direction D1.

In an example embodiment of the present inventive concept, the upper portion of the first preliminary conductive pattern 253 may have a shape of a circle, a square or a square with rounded vertices in a plan view. In this case, the upper portion of the first preliminary conductive pattern 253 may have substantially the same shape as the lower portion of the first preliminary conductive pattern 253.

In another example embodiment of the present inventive concept, the upper portion of the first preliminary conductive pattern 253 may have a shape of a rectangle, or rectangle with rounded vertices having a length in the second direction D2 greater than a length in the first direction D1 in a plan view. In this case, the upper portion of the first preliminary conductive pattern 253 may have a different shape from the lower portion of the first preliminary conductive pattern 253.

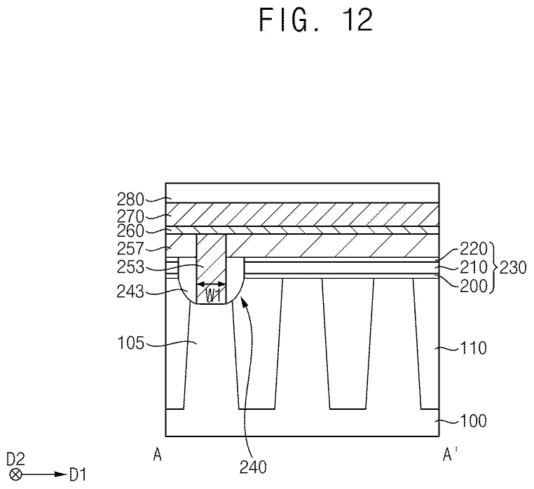

Referring to FIG. 12, after forming a second conductive layer 257 on the first insulating layer structure 230 and the first preliminary conductive pattern 253, an upper portion of the second conductive layer 257 may be planarized until an upper surface of the first preliminary conductive pattern 253 is exposed.

The second conductive layer 257 may include, for example, polysilicon doped with n-type impurities, for example, phosphorus(P) or arsenic(As). In an example embodiment of the present inventive concept, the second conductive layer 257 may include substantially the same material as the first preliminary conductive pattern 253, and thus, the first preliminary conductive pattern 253 and the second conductive layer 257 may be merged with each other. In an example embodiment of the present inventive concept, the second conductive layer 257 may include a different material from the first preliminary conductive pattern 253, and thus, the first preliminary conductive pattern 253 and the second conductive layer 257 may be distinguished from each other.

A first barrier layer 260, a third conductive layer 270 and a second mask layer 280 may be sequentially formed on the first preliminary conductive pattern 253 and the second conductive layer 257. The first preliminary conductive pattern 253, the second conductive layer 257, the first barrier layer 260, the third conductive layer 270 and the second mask layer 280 may collectively form a conductive structure layer.

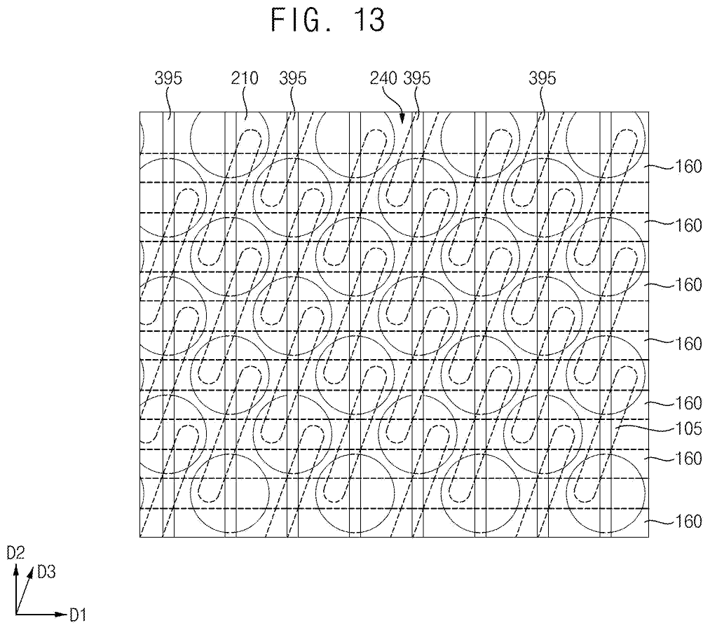

Referring to FIGS. 13 and 14, a first etch stop layer and a first capping layer may be sequentially formed on the conductive structure layer. The first capping layer may be etched to form a first capping pattern 385, and the first etch stop layer, the first mask layer 280, the third conductive layer 270, the first barrier layer 260 and the first conductive layer 250 may be sequentially etched by a second etching process using the first capping pattern 385 as an etching mask.

In example embodiments of the present inventive concept, the first capping pattern 385 may extend in the second direction D2, and a plurality of first capping patterns 385 may be spaced apart from each other in the first direction D1. The first capping pattern 385 may have a second width W2 in the first direction D1. In an example embodiment of the present inventive concept, the second width W2 may be smaller than the first width W1. In an example embodiment of the present inventive concept, the second width W2 may be substantially the same as the first width W1.

During the second etching process, an upper portion of the sacrificial spacer 243 may be exposed, and the exposed upper portion of the sacrificial spacer 243 may also be removed. Accordingly, the sacrificial spacer 243 may remain at a lower portion of the first opening 240.

If the second width W2 of the first capping pattern 385 is smaller than the first width W1 of the first preliminary conductive pattern 253, the upper portion of the first preliminary conductive pattern 253 and an upper portion of the lower portion (e.g., a middle portion) of the first preliminary conductive pattern 243 may also be partially removed, and the first preliminary conductive pattern 253 may be transformed into a first conductive pattern 255. Accordingly, the lower portion of the first preliminary conductive pattern 243 may be divided into a lower portion 255a and a middle portion 255b of the first conductive pattern 255, and the upper portion of the first preliminary conductive pattern 243 may be transformed into an upper portion 255c of the first conductive pattern 255. The lower portion 255a of the first conductive pattern 255 may have the first width W1 in the first direction D1, and the middle portion 255b of the first conductive pattern 255 may have the second width W2 in the first direction D1. The upper portion 255c of the first conductive pattern 255 may have the second width W2 in the first direction D1.

However, if the second width W2 of the first capping pattern 385 is substantially the same as the first width W1 of the first preliminary conductive pattern 253, the upper portion and the upper portion of the lower portion (e.g., the middle portion) the first preliminary conductive pattern 253 might not be partially removed during the second etching process, and accordingly, the lower portion 255a, the middle portion 255b and the upper portion 255c of the first conductive pattern 255, which may be formed by the second etching process, may have a substantially same width in the first direction D1, that is, the first width W1 or the second width W2 as each other.

In FIG. 14, after performing the second etching process, the upper surface of the sacrificial spacer 243 remaining in the first opening 240 may be substantially coplanar with an upper surface of the lower portion 255a of the first conductive pattern 255. However, the present inventive concept is not limited thereto, and the upper surface of the sacrificial spacer 243 may be formed to be higher or lower than the upper surface of the lower portion 255a of the first conductive pattern 255.

During the second etching process, the third insulating layer 220 under the second conductive layer 257 may also be partially etched and remain as a third insulation pattern 225.

By the second etching process, the first conductive pattern 255, a first barrier pattern 265, a third conductive pattern 275, a second mask 285, a first etch stop pattern 365 and the first capping pattern 385 may be sequentially stacked on the first opening 240, and the third insulation pattern 225, the first conductive pattern 255, the first barrier pattern 265, the third conductive pattern 275, the second mask 285, the first etch stop pattern 365 and the first capping pattern 385 may be sequentially stacked on the second insulating layer 210 of the insulating layer structure 230 at an outside of the first opening 240.

Hereinafter, the first and second conductive patterns 255 and 259, the first barrier pattern 265, the third conductive pattern 275, the second mask 285, the first etch stop pattern 365 and the first capping pattern 385 sequentially stacked on each other may be referred to as a bit line structure 395. The first and second conductive patterns 255 and 259, the first barrier pattern 265 and the third conductive pattern 275 may collectively form a conductive structure, and the second mask 285, the first etch stop pattern 365 and the first capping pattern 385 may collectively form an insulation structure.

In example embodiments of the present inventive concept, the bit line structure 395 may extend in the second direction D2, and a plurality of bit line structures 395 may be spaced apart from each other in the first direction D1.

As described above, if the first and second conductive patterns 255 and 259 include substantially the same material as each other, the first and second conductive patterns 255 and 259 may be merged with each other, and if the first and second conductive patterns 255 and 259 include different materials from each other, the first and second conductive patterns 255 and 259 may be distinguished from each other.

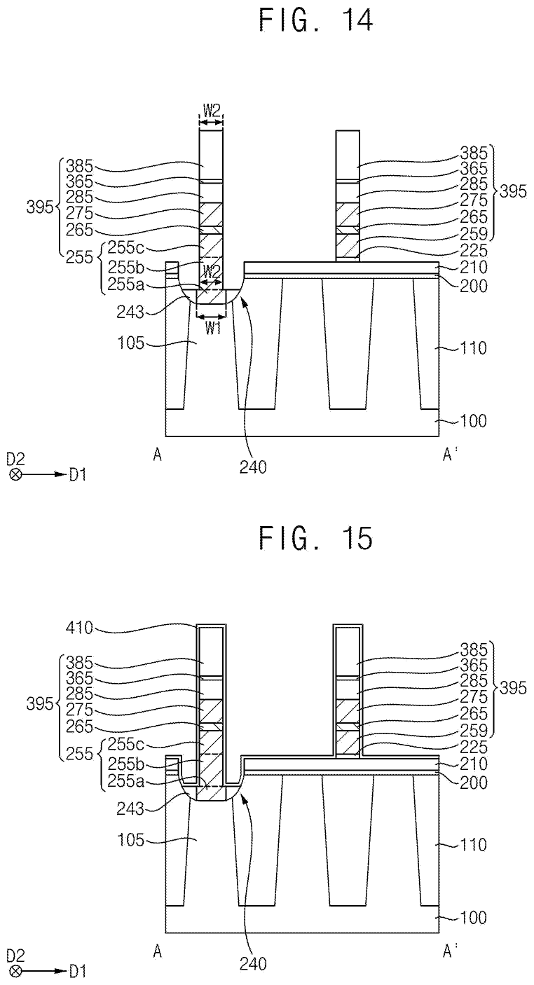

Referring to FIG. 15, a second spacer layer 410 may be formed on the substrate 100 and on the bit line structure 395.

In example embodiments of the present inventive concept, the second spacer layer 410 may be formed by, for example, a deposition process such as an atomic layer deposition (ALD) process, a chemical vapor deposition (CVD) process, a plasma deposition process, etc. The second spacer layer 410 may formed on an upper surface and a sidewall of the bit line structure 395, the upper surface of the sacrificial spacer 243 and sidewalls of the first and second insulating layers 200 and 210 and the third insulating pattern 225.

The second spacer layer 410 may include, for example, silicon oxide, silicon carbonitride, or metal oxide.

Referring to FIG. 16, a heat treatment process may be performed on the substrate 100 to remove the sacrificial spacer 243 that includes a polymer which decomposes at a low temperature, for example, equal to or less than about 300° C.

Accordingly, a first spacer 245 may be formed in a space from which the sacrificial spacer 243 is removed, that is, in a space surrounded or enclosed by a lower sidewall of the first opening 240, a sidewall of the lower portion 255a of the first conductive pattern 255, and a lower surface of a portion of the first spacer layer 410 in the first opening 240. The first spacer 245 may include air with a low dielectric constant.

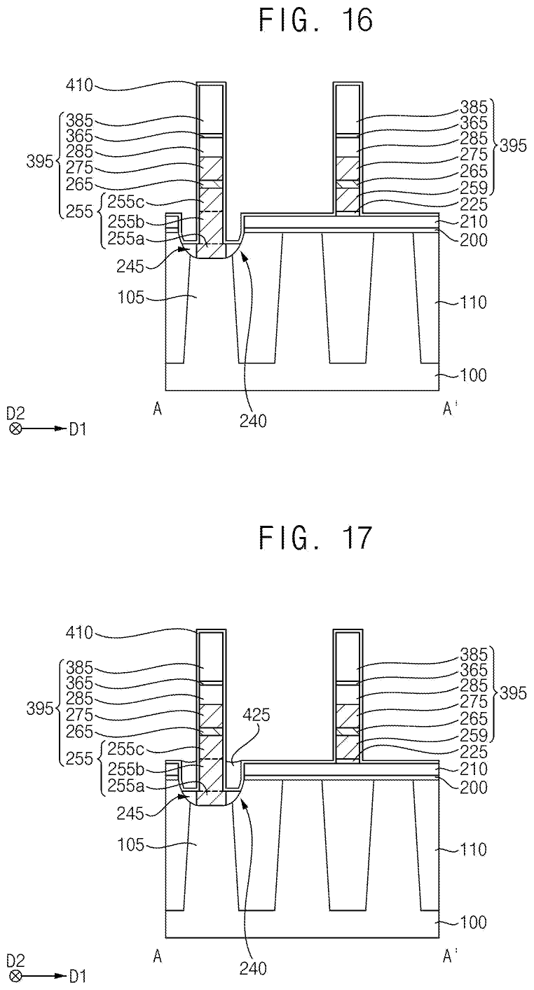

Referring to FIG. 17, a third spacer layer may be formed on the second spacer layer 410, and an upper portion of the third spacer layer may be etched to form a third spacer 425 that fills a remaining portion of the first opening 240.

The third spacer layer may be formed by, for example, a deposition process such as an atomic layer deposition (ALD) process, a chemical vapor deposition (CVD) process, etc., and may include a nitride, for example, silicon nitride.

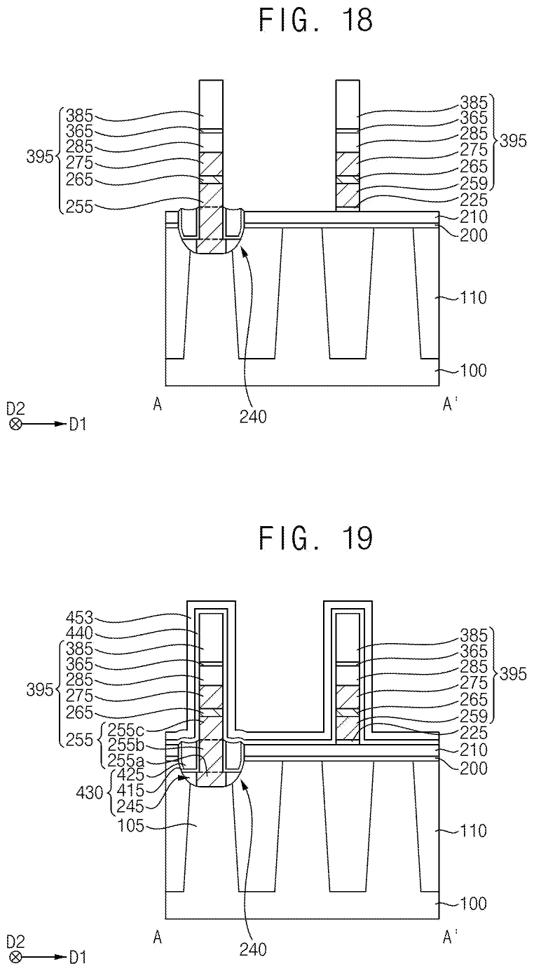

Referring to FIG. 18, a portion of the second spacer layer 410, which is disposed on an upper surface of the second insulating layer 210 and an upper sidewall and the upper surface of the bit line structure 395, may be partially removed by performing a wet etching process and/or a dry etching process.

Accordingly, the upper sidewall and the upper surface of the bit line structure 395 may be exposed, and the second spacer layer 410 may be transformed to a second spacer 415 that covers a lower surface of the third spacer 425. The first to third spacers 245, 415 and 425 may collectively form a first lower spacer structure 430.

Referring to FIG. 19, a fourth spacer layer 440 and a fifth spacer layer 453 may be sequentially formed on the exposed upper sidewall and the exposed upper surface of the bit line structure 395, the sidewall of the third insulation pattern 225, an upper surface of the first lower spacer structure 430 and the upper surface of the second insulating layer 210.

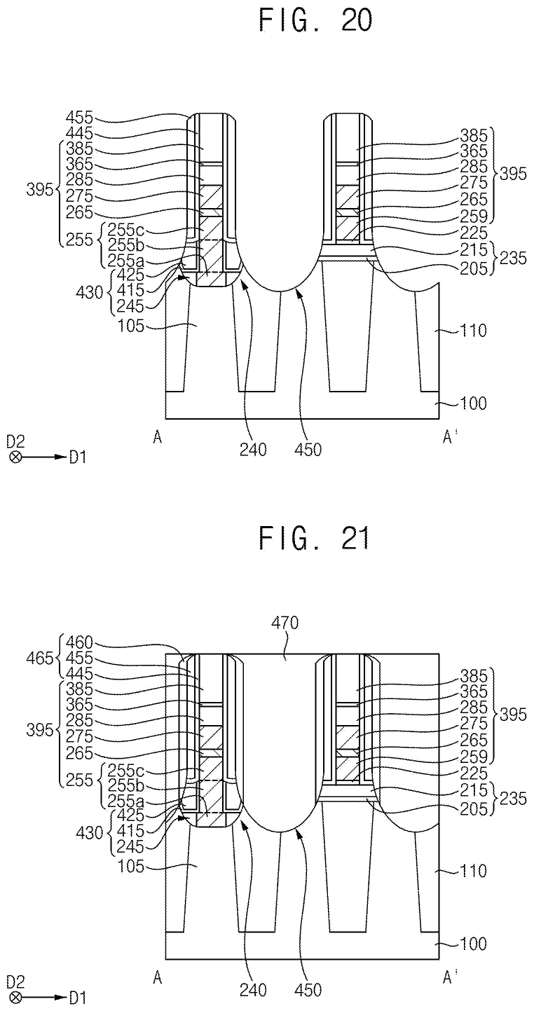

Referring to FIG. 20, the fourth and fifth spacer layers 440 and 453 may be anisotropically etched to form fourth and fifth spacers 445 and 455, respectively, on the sidewall of the bit line structure 395, the sidewall of the third insulation pattern 225 and the upper surface of the first lower spacer structure 430.

A dry etching process may be performed using the first capping pattern 385 and the fourth and fifth spacers 445 and 455 as an etching mask to partially remove the first and second insulating layers 200 and 210, and an upper portion of the active pattern 105 and upper portions of the isolation pattern 110 and the gate mask 150 adjacent thereto may also be removed by the dry etching process to form a second opening 450.

By the dry etching process, the first and second insulating layers 200 and 210 may be partially removed to remain as first and second insulation patterns 205 and 215, respectively, under the bit line structure 395. The first to third insulation patterns 205, 215 and 225 sequentially stacked on each other under the bit line structure 395 may form a first insulation pattern structure.

Referring to FIG. 21, a sixth spacer layer may be formed on an upper surface of the first capping pattern 385, an upper surface of the fourth spacer 445, an upper surface and an outer sidewall of the fifth spacer 455, a portion of the upper surface of the first lower spacer structure 430, and upper surfaces of the active pattern 105, the isolation pattern 110 and the gate mask 150 that are exposed by the second opening 450. The sixth spacer layer may be anisotropically etched to form a sixth spacer 460 on the outer sidewall of the fifth spacer 455 and on the portion of the upper surface of the first lower spacer structure 430.

The fourth to sixth spacers 445, 455 and 460, which are sequentially stacked on the sidewall of the bit line structure 395 in the horizontal direction, may be referred to as an upper spacer structure 465.

A sacrificial layer may be formed to fill the second opening 450 on the substrate 100 to a sufficient height, and an upper portion of the sacrificial layer may be planarized until the upper surface of the first capping pattern 385 is exposed to form a sacrificial pattern 470 in the second opening 450.

In example embodiments of the present inventive concept, the sacrificial pattern 470 may extend in the second direction D2, and a plurality of sacrificial patterns 470 may be spaced apart from each other in the first direction D1 by the bit line structures 395. The sacrificial pattern 470 may include, for example, an oxide such as silicon oxide.

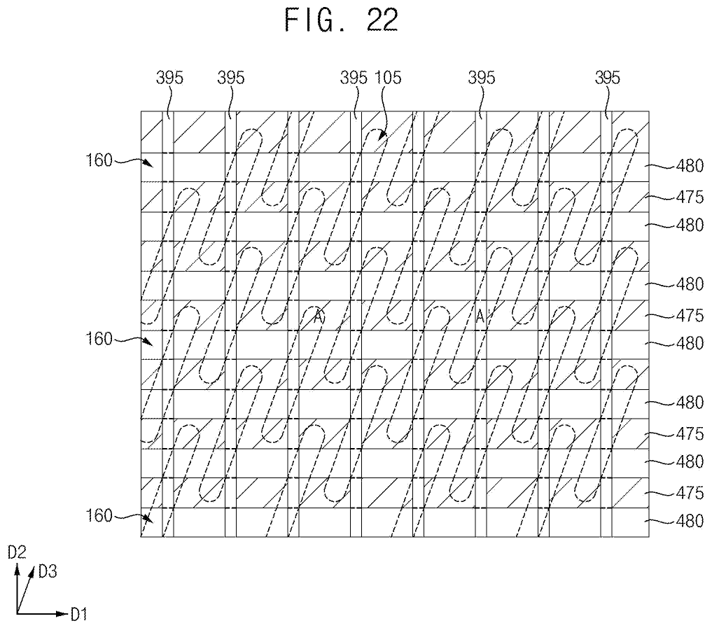

Referring to FIGS. 22 and 23, a third mask including a plurality of third openings, each of which may extend in the first direction D1 and may be spaced apart from each other in the second direction D2 may be formed on the first capping pattern 385, the sacrificial pattern 470 and the upper spacer structure 465, and the sacrificial pattern 470 may be etched by using the third mask as an etching mask.

In example embodiments of the present inventive concept, each of the third openings may overlap the gate structures 160 in the vertical direction. By the etching process, a fourth opening exposing upper surfaces of the gate structures 160 may be formed between the bit line structures 395 on the substrate 100. The sacrificial pattern 470 extending in the second direction D2 between the bit line structures 395 may be divided into a plurality of pieces in the second direction D2.

After removing the third mask, a second capping pattern 480 may be formed to fill the fourth opening.

The sacrificial pattern 470 may be removed to form a fifth opening exposing the upper surface of the active pattern 105 and an upper portion of the isolation pattern 110 adjacent thereto, and a lower contact plug layer may be formed on the first and second capping patterns 385 and 480 and the upper spacer structure 465, and an upper portion of the lower contact plug 475 may be planarized until upper surfaces of the first and second capping patterns 385 and 480 and the upper spacer structure 465 are exposed.

Accordingly, the lower contact plug layer extending in the second direction D2 between the bit line structures 395 may be divided into a plurality of lower contact plugs 475 spaced apart from each other in the second direction D2.

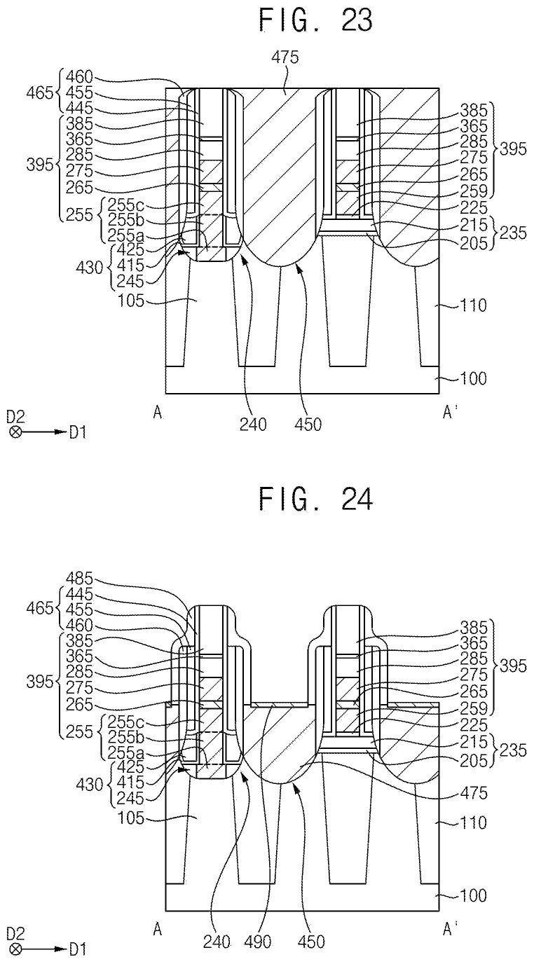

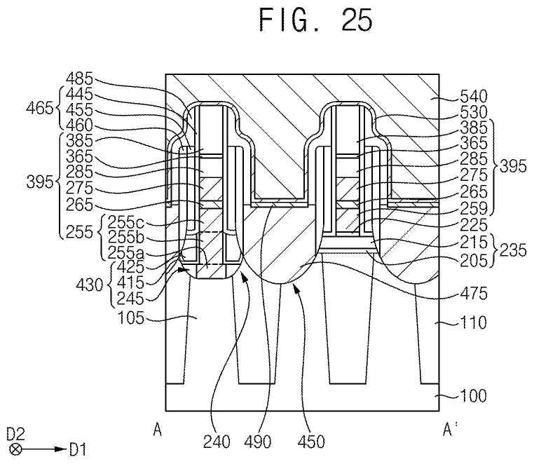

Referring to FIG. 24, an upper portion of the lower contact plug 475 may be removed to expose an upper portion of the upper spacer structure 465 on the sidewall of the bit line structure 395, and upper portions of the fifth and sixth spacers 455 and 460 of the exposed upper spacer structure 465 may be removed.

An upper portion of the lower contact plug 475 may be additionally removed. Thus, an upper surface of the lower contact plug 475 may be lower than upper surfaces of the fifth and sixth spacers 455 and 460.

A seventh spacer layer may be formed on the bit line structure 395, the upper spacer structure 465, the second capping pattern 480 and the lower contact plug 475, and may be anisotropically etched to form a seventh spacer 485 covering an upper portion of the upper spacer structure 465 on the sidewall of the bit line structure 395, and the upper surface of the lower contact plug 475 may be exposed by the etching process.

A metal silicide pattern 490 may be formed on the exposed upper surface of the lower contact plug 475. In example embodiments of the present inventive concept, the metal silicide pattern 490 may be formed by forming a first metal layer on the first and second capping patterns 385 and 480, the seventh spacer 485 and the lower contact plug 475, by performing a heat treatment thereon, and by removing an unreacted portion of the first metal layer.

Referring to FIG. 25, a second barrier layer 530 may be formed on the first and second capping patterns 385 and 480, the seventh spacer 485, the metal silicide pattern 490 and the lower contact plug 475, and a second metal layer 540 may be formed on the second barrier layer 530 to fill a space between adjacent bit line structures 395.

A planarization process may be performed on an upper portion of the second metal layer 540. The planarization process may include, for example, a chemical mechanical polishing (CMP) process and/or an etch-back process.

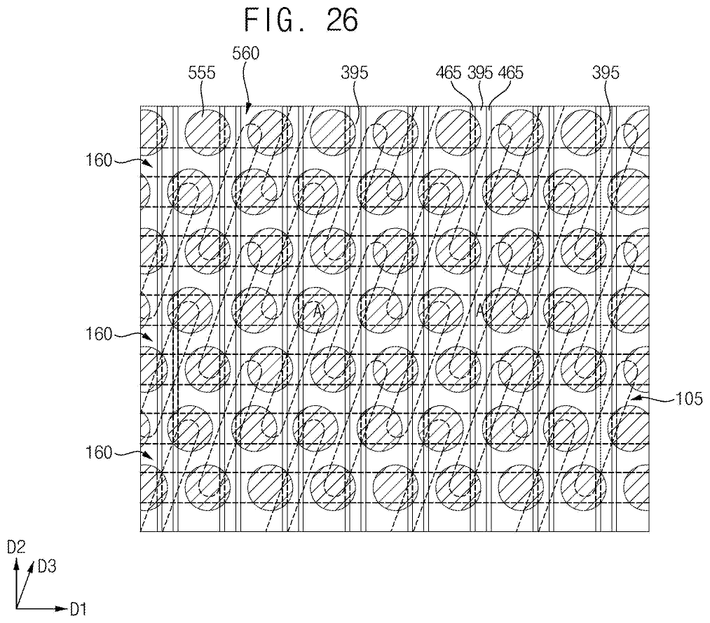

Referring to FIGS. 26 and 27, the second metal layer 540 and the second barrier layer 530 may be patterned to form an upper contact plug 555. In example embodiments of the present inventive concept, a plurality of upper contact plugs 555 may be formed, and a sixth opening 560 may be formed between adjacent upper contact plugs 555.

The sixth opening 560 may be formed by partially removing the first and second capping patterns 385 and 480, the upper spacer structure 465 and the seventh spacer 485 as well as the second metal layer 540 and the second barrier layer 530. In example embodiments of the present inventive concept, the upper contact plug 555 may be arranged, for example, in a honeycomb pattern or in a lattice pattern in the first and second directions D1 and D2, in a plan view.

The lower contact plug 475, the metal silicide pattern 490 and the upper contact plug 555, which are sequentially stacked on each other on the substrate 100, may collectively form a contact plug structure.

Referring to FIG. 28, a fourth insulation pattern 570 may be formed on a bottom and a sidewall of the sixth opening 560, and a fifth insulation pattern 580 may be formed to fill a remaining portion of the sixth opening 560. The fifth insulation pattern 580 may be disposed on the fourth insulation pattern 570.

Each of the fourth and fifth insulation patterns 570 and 580 may form a second insulation pattern structure 590.

In an example embodiment of the present inventive concept, before forming the fourth insulating pattern 570, the fifth spacer 455 included in the upper spacer structure 465 exposed by the sixth opening 560 may be removed to form an air gap. In this case, a top end of the air gap may be covered by the fourth insulation pattern 570, and thus, an air spacer 435 may be formed.

Referring to FIGS. 1 and 2 again, a capacitor contacting an upper surface of the upper contact plug 555 may be formed.

For example, a second etch stop pattern 600 and a mold layer may be sequentially formed on the second insulating pattern structure 590 and the upper contact plug 555. In addition, a seventh opening may be formed to expose an upper surface of the upper contact plug 555.

The seventh openings respectively exposing the upper contact plugs 555 may be arranged, depending on the arrangement of the upper contact plugs 555, in a honeycomb pattern or a lattice pattern in a plan view.

A lower electrode 610 having a shape of a pillar or cylinder may be formed in the seventh opening. The mold layer may be removed, and a dielectric layer 620 and an upper electrode 630 may be sequentially formed on the lower electrode 610 and the second etch stop pattern 600. The lower electrode 610, the dielectric layer 620 and the upper electrode 630 may collectively form the capacitor 640.

In some embodiments of the present inventive concept, the lower electrode 610 may have a shape of a cylinder in the seventh opening.

Upper wirings may be additionally formed on the capacitor 640, and the manufacturing of the semiconductor device may be completed.

As illustrated above, the sacrificial spacer 243 including a polymer that decomposes at a low temperature may be formed on the sidewall of the first opening 240. In addition, the first conductive layer 250 filling the remaining portion of the first opening 240 may be formed, and the upper portion of the first conductive layer 250 may be etched to form the first preliminary conductive pattern 253. Thereafter, the second conductive layer 257, the first barrier layer 260, the third conductive layer 270 and the second mask layer 280 may be formed on the sacrificial spacer 243 and the first preliminary conductive pattern 253, and may be patterned to form the bit line structure 395.

For example, instead of forming the sacrificial spacer 243 and the first preliminary conductive pattern 253 in the first opening 240, a conductive layer may be formed in the first opening 240, and other layers, that is, the second conductive layer 257, the first barrier layer 260, the third conductive layer 270 and the second mask layer 280, may be formed on the conductive layer. In this case, during an etching process for forming the bit line structure, a total thickness of layers to be etched during the pattering process may be so large that the underlying conductive layer might not be easily etched. For example, if a width of the first opening 240 is small, a portion of the conductive layer in the lower portion of the first opening 240 might not be etched to remain on the sidewall of the first opening 240. Thus, an electrical short may occur between the conductive layer and the lower contact plug 475 adjacent thereto.

However, in example embodiments of the present inventive concept, the sacrificial spacer 243 may be formed on the sidewall of the first opening 240 to secure an internal space that may be spaced apart from the sidewall of the first opening 240. In addition, the first conductive layer 250 may be formed within the internal space, and the upper portion of the first conductive layer 250 may be patterned to form the first preliminary conductive pattern 253. Thus, the first preliminary conductive pattern 253 might not contact the sidewall of the first opening 240, and accordingly, an electrical short between the lower contact plug 475 and the bit line structure 395 including the first conductive pattern 255, to which the first preliminary conductive pattern 253 is transformed, may be prevented.

In addition, the first conductive pattern 255 of the bit line structure 395 within the first opening 240 might not be etched simultaneously with the overlying layers, but may be etched before etching the overlying layers. Therefore, the process for forming the bit line structure 395 may be performed easily, and tilting of the bit line structure 395 may be reduced or prevented.

In addition, the sacrificial spacer 243 may include a polymer that is easily decomposed at low temperature, and thus, the sacrificial spacer 243 may be converted into the first spacer 245 including air by a subsequent heat treatment process. Accordingly, the first spacer 245 including air with a low dielectric constant may be formed between the bit line structure 395 and the lower contact plug 475, so that parasitic capacitance between the bit line structure 395 and the lower contact plug 475 may be reduced.

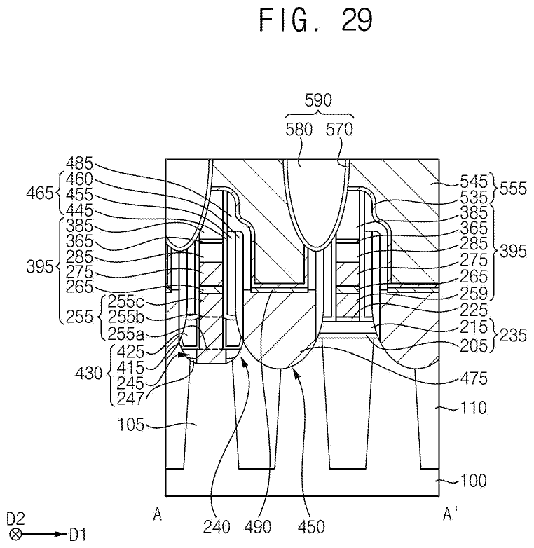

FIG. 29 is a cross-sectional view illustrating a semiconductor device in accordance to example embodiments of the present inventive concept.

This semiconductor device is substantially the same as or similar to the semiconductor device illustrated with reference to FIGS. 1 and 2, except for further including an eighth spacer 247, and thus, repeated explanations may be omitted or briefly discussed herein.

Referring to FIG. 29, the semiconductor device may further include the eighth spacer 247 covering a lower surface of the first spacer 425, and the first, second, third and eighth spacers 245, 415, 425 and 247 may collectively form a second lower spacer structure 249.

Unlike processes illustrated with FIG. 16, the sacrificial spacer 241 might not be completely removed by the heat treatment process, but may partially remain, and the remaining portion of the sacrificial spacer 241 may be referred to as the eighth spacer 247. Thus, the eighth spacer 247 may include a material substantially the same as that of the sacrificial spacer 241.

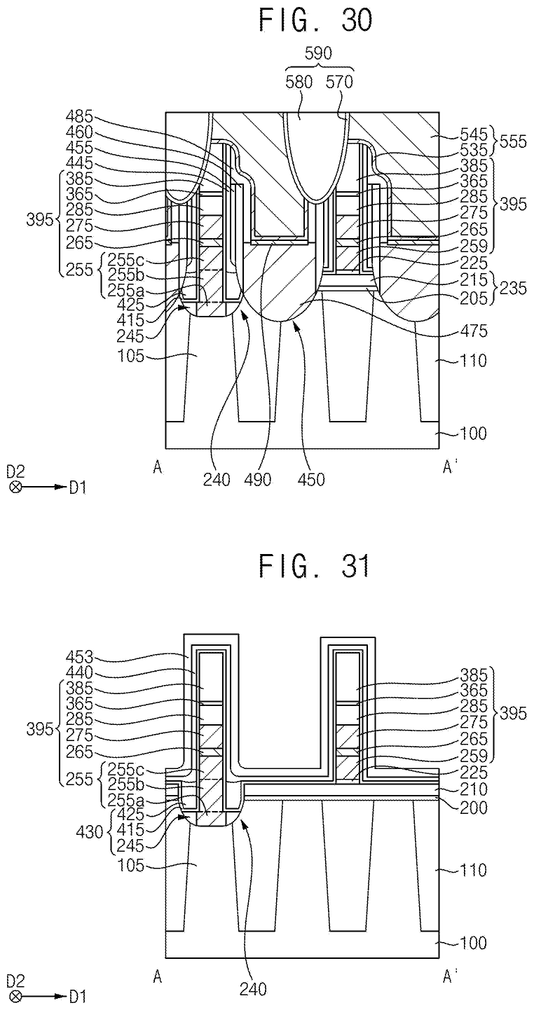

FIG. 30 is a cross-sectional view illustrating a semiconductor device in accordance to example embodiments of the present inventive concept.

This semiconductor device is substantially the same as or similar to the semiconductor device illustrated with reference to FIGS. 1 and 2 except for some elements, and thus, repeated explanations may be omitted or briefly discussed herein.

Referring to FIG. 30, instead of including the first lower spacer structure 430 and the upper spacer structure 465, the semiconductor device may include a second spacer 415 on a top end of the first spacer 245 and covering the sidewall of the bit line structure 395 except for the sidewall of the lower portion 255a of the first conductive pattern 255. The semiconductor device may further include a third spacer 425 disposed on a lower portion of an outer sidewall of the second spacer 415, and a fourth spacer 445 disposed on the third spacer 425 and covering an upper portion of the outer sidewall of the second spacer 415. The semiconductor device may additionally include a fifth spacer 455 disposed on a lower portion of an outer sidewall of the fourth spacer 445, and a sixth spacer 460 disposed on an outer sidewall of the fifth spacer 455. The semiconductor device may also include a seventh spacer 485 contacting an upper portion of the outer sidewall of the fourth spacer 445, an upper surface of the fifth spacer 455 and an upper surface and an upper portion of an outer sidewall of the sixth spacer 460.

FIG. 31 is a cross-sectional view illustrating a method of manufacturing a semiconductor device in accordance to example embodiments of the present inventive concept.

This method is substantially the same as or similar to those illustrated with reference to FIGS. 3 and 28 and FIGS. 1 and 2, and thus, repeated explanations may be omitted or briefly discussed herein.

Processes substantially the same as or similar to those illustrated with reference to FIGS. 2 to 17 may be performed.

Referring to FIG. 31, unlike the processes illustrated with reference to FIGS. 18 and 19, an etching process is not performed on the second spacer layer 410, and the third and fourth spacer layers 440 and 453 may be formed.

Accordingly, the first spacer 415 may cover the upper sidewall and the upper surface of the bit line structure 395.

Thereafter, processes substantially the same as or similar to those illustrated with reference to FIGS. 20 to 28 and FIGS. 1 and 2 may be performed to complete manufacturing of the semiconductor device.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device, comprising:
an active pattern disposed on a substrate;
a gate structure disposed on an upper portion of the active pattern;
a bit line structure disposed on the active pattern, wherein the bit line structure includes a first conductive pattern, a second conductive pattern and an insulation structure stacked on each other in a vertical direction substantially perpendicular to an upper surface of the substrate;
a lower spacer structure disposed on a lower portion of a sidewall of the bit line structure;
an upper spacer structure disposed on the lower spacer structure, wherein the upper spacer structure is disposed on an upper portion of the sidewall of the bit line structure;
a contact plug structure disposed on the active pattern, wherein the contact plug structure is spaced apart from the bit line structure; and
a capacitor disposed on the contact plug structure,
wherein the lower spacer structure includes:
a first spacer partially covering a sidewall of the first conductive pattern, and including air; and
a second spacer disposed on the first spacer.

2. The semiconductor device of claim 1, wherein the first conductive pattern includes:
a lower portion contacting an upper surface of the active pattern;
a middle portion disposed on the lower portion; and
an upper portion disposed on the middle portion, and
wherein the first spacer covers a sidewall of the lower portion of the first conductive pattern, and the second spacer covers a sidewall of the middle portion of the first conductive pattern.

3. The semiconductor device of claim 2, wherein the second spacer covers a sidewall of the upper portion of the first conductive pattern.

4. The semiconductor device of claim 2, further comprising a third spacer disposed below the first spacer and contacting the sidewall of the lower portion of the first conductive pattern, wherein the third spacer includes a polymer that decomposes at a temperature equal to or less than about 300° C.

5. The semiconductor device of claim 2, wherein each of the lower portion, the middle portion and the upper portion of the first conductive pattern has a shape of a cylinder, a square pillar or a square pillar with rounded vertices.

6. The semiconductor device of claim 2, wherein each of the lower portion and the middle portion of the first conductive pattern has a shape of a cylinder, a square pillar or a square pillar with rounded vertices, and the upper portion of the first conductive pattern has a shape of a rectangular pillar or a rectangular pillar with rounded vertices.

7. The semiconductor device of claim 2, wherein a first width of the lower portion of the first conductive pattern is greater than a second width of each of the middle portion and the upper portion of the first conductive pattern.

8. The semiconductor device of claim 2, further comprising:
an isolation pattern disposed on the substrate and covering a sidewall of the active pattern; and
an insulation pattern structure disposed on the active pattern and the isolation pattern,
wherein the gate structure extends in a first direction substantially parallel to the upper surface of the substrate and is disposed on the upper portion of the active pattern and an upper portion of the isolation pattern, and
wherein the bit line structure extends in a second direction and is disposed on the active pattern and the insulation pattern structure, wherein the second direction is substantially parallel to the upper surface of the substrate and crosses the first direction.

9. The semiconductor device of claim 8, wherein the bit line structure further includes:
a third conductive pattern disposed on the insulation pattern structure, wherein the third conductive pattern is disposed on the upper portion of the first conductive pattern.

10. The semiconductor device of claim 9, wherein each of the first and third conductive patterns includes polysilicon doped with n-type impurities.

11. The semiconductor device of claim 8, wherein an upper surface of the middle portion of the first conductive pattern is substantially coplanar with an upper surface of the insulation pattern structure.

12. The semiconductor device of claim 1, wherein the lower spacer structure further includes a third spacer whose bottom and a sidewall are covered by the second spacer, and
wherein the upper spacer structure includes a fourth spacer, a fifth spacer and a sixth spacer sequentially stacked on each other on the upper sidewall of the bit line structure in a horizontal direction substantially parallel to the upper surface of the substrate.

13. A semiconductor device, comprising:
an active pattern disposed on a substrate;
an isolation pattern disposed on the substrate, wherein the isolation pattern covers a sidewall of the active pattern;
a gate structure disposed on an upper portion of the active pattern and an upper portion of the isolation pattern, wherein the gate structure extends in a first direction substantially parallel to an upper surface of the substrate;
an insulation pattern structure disposed on the active pattern, the isolation pattern and the gate structure;
a bit line structure extending on the active pattern and the insulation pattern structure in a second direction, wherein the second direction is substantially parallel to the upper surface of the substrate and crosses the first direction, and wherein the bit line structure includes a first conductive pattern structure, a second conductive pattern and an insulation structure sequentially stacked in a vertical direction substantially perpendicular to the upper surface of the substrate;
a lower spacer structure disposed on a lower portion of a sidewall of the bit line structure, and including a first spacer, a second spacer and a third spacer;
an upper spacer structure disposed on the lower spacer structure and on an upper portion of the sidewall of the bit line structure;
a contact plug structure disposed on the active pattern, and spaced apart from the bit line structure; and
a capacitor disposed on the contact plug structure,
wherein the first conductive pattern structure includes a lower portion, a middle portion and an upper portion sequentially stacked on each other in the vertical direction, and
wherein a first width, in the first direction, of the lower portion of the first conductive pattern structure is greater than a second width, in the first direction, of the middle portion of the first conductive pattern structure.

14. The semiconductor device of claim 13, wherein the upper spacer structure is disposed on a sidewall of the upper portion of the first conductive pattern structure, and
wherein a third width, in the first direction, of the upper portion of the first conductive pattern structure is substantially the same as the second width, in the first direction, of the middle portion of the first conductive pattern.

15. The semiconductor device of claim 13, wherein the upper portion of the first conductive pattern structure includes a first portion and a second portion, wherein the first portion contacts an upper surface of the middle portion of the first conductive pattern structure, and the second portion contacts an upper surface of the insulation pattern structure, and
wherein each of the first and second portions includes polysilicon doped with n-type impurities.

16. The semiconductor device of claim 13, wherein the first spacer includes air.

17. The semiconductor device of claim 13, wherein the lower spacer structure further includes a fourth spacer that is disposed below the first spacer, and contacts a sidewall of the lower portion of the first conductive pattern structure, wherein the fourth spacer includes a polymer that decomposes at a temperature equal to or less than about 300° ° C.

18. A semiconductor device, comprising:
an active pattern disposed on a substrate;
a gate structure disposed on an upper portion of the active pattern;
a bit line structure disposed on the active pattern, wherein the bit line structure includes a first conductive pattern, a second conductive pattern and an insulation structure stacked on each other in a vertical direction substantially perpendicular to an upper surface of the substrate;
a lower spacer structure disposed on a lower portion of a sidewall of the bit line structure;
an upper spacer structure disposed on the lower spacer structure, and disposed on an upper portion of the sidewall of the bit line structure;
a contact plug structure disposed on the active pattern, wherein the contact plug structure is spaced apart from the bit line structure; and
a capacitor disposed on the contact plug structure,
wherein the first conductive pattern includes:
a lower portion contacting an upper surface of the active pattern;
a middle portion disposed on the lower portion; and
an upper portion disposed on the middle portion,
wherein the upper portion of the first conductive pattern has a shape of a rectangular pillar or a rectangular pillar with rounded vertices, and
wherein the lower spacer structure covers sidewalls of the lower portion and the middle portion of the first conductive pattern, and the upper spacer structure covers a sidewall of the upper portion of the first conductive pattern.

19. The semiconductor device of claim 18, wherein a first width of the lower portion of the first conductive pattern is greater than a second width of each of the middle portion and the upper portion of the first conductive pattern.

20. The semiconductor device of claim 18, wherein the lower spacer structure includes air.
